(19) United States
(12) Patent Application Publication
(10) Pub. No.: US 2001/0026444 A1
(43) Pub. Date: Oct. 4, 2001

(54) Electronic circuit board with built-in thin film capacitor and manufacturing method thereof

(76) Inventors: Naoki Matsushima, Yokohama (JP); Eiji Matsuzaki, Yokohama (JP); Hidetaka Shigi, Ashikagashimo (JP); Yasunori Narizuka, Hiratsuka (JP); Tetsuya Yamazaki, Fujisawa (JP); Kazuhiko Horikoshi, Kawasaki (JP); Yoichi Abe, Yamato (JP); Shosaku Ishihara, Chigasaki (JP); Kiyoshi Ogata, Yokohama (JP); Toshiyuki Arai, Machida (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/765,413

(22) Filed: Jan. 22, 2001

(30) Foreign Application Priority Data
Jan. 21, 2000 (JP) 2000-017758

(51) Int. Cl. H05K 1/16

(52) U.S. Cl. 361/763; 361/765; 361/760

(57) ABSTRACT

In the present invention, a thin film capacitor, having a dielectric layer of a metal oxide having perovskite crystal structure, is formed on a first substrate before the capacitor is transferred onto a second substrate on which an electronic circuit has been formed. Thereafter, patterning of the capacitor and electrical connection are to be carried out.

This application is based on Japanese Patent Application No. 2000-017758 filed on Jan. 21, 2000, the contents of which are incorporated hereinto by reference.

### BACKGROUND OF THE INVENTION

1. Field of the Invention

The present invention relates to an electronic circuit board with a built-in capacitor and a manufacturing method of the board, and particularly to an electronic circuit board with a built-in thin film capacitor having a high quality and high reliability which enables a high speed transmission of a high frequency signal and a manufacturing method of the circuit board.

2. Description of the Related Art

Recently, for an electronic circuit board, required is transmission of signals at a higher speed and in a higher frequency band region. Accompanied with this, possibility of occurrence of error signals due to noises generated in power source tends to increase. Particularly, in a high performance electronic computer using C-MOS LSIs, the phenomenon becomes a serious problem.

One of effective countermeasures for suppressing the occurrence of the phenomenon is to mount a bypass capacitor between the power source and the LSI elements. Items of the specification required for the bypass capacitor to contribute to noise reduction in higher frequency band region include, in addition to providing a large capacitance, providing a small inductance between the capacitor and the LSI element.

A capacitance C of a capacitor having a lamination structure of an electrode/an insulator (a dielectric material)/an electrode is generally given, as well-known, as C=εᵣ×ε₀×S/d (where, εᵣ: relative dielectric constant of the dielectric material, εₒ: dielectric constant of vacuum, S: electrode area of the capacitor, d: film thickness of the dielectric material). Thus, as a measure for increasing the capacitance, it is considered to increase the relative dielectric constant, increase the electrode area, and reduce the film thickness of the dielectric material.

However, increase in the electrode area provides fear of causing an increase in self-inductance, and reduction in the film thickness will further cause a danger of interelectrode short-circuit.

Therefore, as a very effective measure for increasing the capacitance C, it is considered to increase a relative dielectric constant of the dielectric material, in other words, to use a dielectric material with a large dielectric constant.

As materials having large dielectric constants, there are known metal oxides having perovskite crystal structures. They are specifically named as strontium titanate, strontium barium titanate, lead magnesium niobate, barium titanate, lead zirconium titanate, strontium bismuth tantalate, and metal oxides including the above, preferably as main components.

Meanwhile, the most effective method of reducing inductance between the capacitor and the LSI chip is to shorten the interconnection therebetween as much as possible.

In an ordinary electronic circuit board that has been conventionally often used, the capacitor is provided by a method in which, in the same way as the LSI element, a chip capacitor is mounted on the electronic circuit board by means of soldering connection or the like for providing them as a bypass capacitor.

In the method, however, there are limitations in reducing distance from the capacitor to the LSI. Thus, in order to further shorten the transmission path, studies were made on a method for providing a built-in capacitor in the electronic circuit board.

For example, in the paragraph [0005] in JP-A-935997/1997, there is disclosed a module 15 with a built-in thin film capacitor having a thin film capacitor 13 provided on a board 10 for module. The thin film capacitor has a thin film multi-layer circuit 14 provided thereon. It is further disclosed that the board 10 for module is provided with a sintered ceramics 11 of AlN, Al₂O₃, or SiC, and a glass layer 12 provided on the surface of the sintered ceramics 11.

In the above described related art, the thin film multi-layer circuit 14 exists between the thin film capacitor 13 and the LSI 14d disposed on the thin film multi-layer circuit 14. This shows a drawback in that the inductance component of a through hole interconnection on the thin film multi-layer circuit 14 largely affects the characteristics of the module circuit when a frequency of a transmitted signal is increased.

Therefore, it is indispensable for avoiding the above problem to form the thin film capacitor 13 on the thin film multi-layer circuit 14. Ideally, it is further necessary even to consider an effect of an inductance of ball solder used for connecting the thin film multi-layer circuit 14 and the LSI 14d. Thus, it is required as being desirable to form the thin film capacitor 13 directly above the electrodes of the LSI element 14d or in a rearrangement interconnection layer of the LSI element 14d provided for forming a solder bump.

However, a problem arises in forming a bypass capacitor in the thin film interconnection layer of the electronic circuit board, directly above the electrodes of the LSI element, or in the rearrangement interconnection layer of the LSI element by using a material with a large dielectric constant. The problem is in that the electronic circuit board such as the LSI element can not withstand heating temperatures necessary for forming the above thin film capacitor with a material having a large dielectric constant, namely, a material having perovskite crystal structure.

In forming a metal oxide thin film having perovskite crystal structure, a heat treatment step is indispensable for crystallization, repair of oxygen deficiency or the like regardless of a formation method.

The specific heat treatment temperatures are different depending on film formation methods or kinds of the metal oxides. For example, in depositing strontium barium titanate by sputtering, it is necessary to bring the temperature at sputtering up to 450° C. or above for obtaining the perovskite crystal structure. For lead magnesium niobate, a heat treatment at about 600° C. or above is necessary. Although the strontium titanate crystallizes at the lowest temperature among the above metal oxides, it still requires to be heated at 350° C. or above. It crystallizes to some extent at a temperature of the order of 200° C. However, in this case the relative dielectric constant obtained is so low that there is provided little advantage over dielectric materials without perovskite crystal structure such as tantalum oxide and silicon nitride.

Incidentally, an organic insulation film such as polyimide is formed as a passivation film on the surface of the LSI chip. Also in forming a rearrangement interconnection layer for a solder bump, it is general to use an organic insulation film such as polyimide as the thin film insulation layer thereof. Further, in an electronic circuit board mounting the LSI, element or the like, an organic insulation layer with low dielectric constant represented by polyimide is usually used for obtaining good characteristics of an electronic circuit thereof.

Polyimide is a heat-resistant resin that can withstand higher temperatures. It has, however, a thermal decomposition temperature of the order of 450° C. and its characteristics are degraded even at a temperature of the order of 350° C. in the presence of high concentration oxygen in an atmosphere. In addition, when heated at a temperature of the order of 300° C., polyimide is remarkably softened.

Therefore, when a thin film is formed on the polyimide, the softened polyimide releases the stress in the thin film to cause the thin film to generate wrinkles or cracks with a high possibility. When the thin film is of a thin film capacitor, the above phenomenon causes short-circuit that makes the capacitor defective to make it impossible to stably provide a thin film capacitor with good characteristics.

### SUMMARY OF THE INVENTION

In view of the foregoing, it is an object of the present invention to provide an electronic circuit board with a built-in thin film capacitor on which there is mounted near an LSI element a thin film capacitor that uses a high dielectric material having perovskite crystal structure. Thus provided electronic circuit board with a built-in thin film capacitor has such a high quality and high reliability as to generate no signal error due to noises in power source when transmitting a high frequency signal.

For solving the above described problems and providing an electronic circuit board with a built-in thin film capacitor having high quality and high reliability, an electronic circuit board with a built-in capacitor according to the present invention is made so as to comprise a first substrate having an interconnection part; a capacitor having a dielectric layer sandwiched between an upper electrode and a lower electrode; an adhesion layer; and a protection film, in which board the upper electrode of the capacitor is disposed so as to be in contact with the adhesion layer for being connected to the first substrate, and the upper electrode and the lower electrode are connected to the interconnection part of the first substrate through holes provided in the adhesion layer and the protection film, respectively.

Moreover, instead of the adhesion layer, a junction metal layer is provided on the upper electrode of the capacitor. The junction metal layer is connected to one interconnection in the interconnection part disposed on the first substrate, and the lower electrode is made so as to be connected to the other interconnection in the interconnection part on the first substrate via a through hole provided in the protection film.

Furthermore, in the present invention, the adhesion layer is made to be an anisotropic conductive adhesion layer. There, the upper electrode of the capacitor is disposed so as to be connected to one interconnection part on the first substrate via the anisotropic conductive adhesion layer, and the lower electrode is made so as to pass via a through hole provided in the protection film and be connected to the other interconnection in the interconnection part on the first substrate via the anisotropic conductive adhesion layer.

The dielectric layer is a metal oxide having perovskite crystal structure, for which there used at least one of strontium titanate, strontium barium titanate, lead magnesium niobate, barium titanate, lead zirconium titanate, strontium bismuth tantalate, and metal oxides including the above, preferably as main components.

In addition, in the present invention, each of the upper electrode and the lower electrode is made to comprise at least two metal layers in which, compared with a resistance of one metal layer disposed to be in contact with the dielectric layer, a resistance of the other metal layer made smaller, and for the first substrate used is a semiconductor device comprising the interconnection part and a transistor part.

The above described electronic circuit board with a built-in capacitor is manufactured by the following method.

Namely, the method is that of manufacturing an electronic circuit board with a built-in capacitor, comprising a first substrate with an interconnection part, a capacitor having a dielectric layer sandwiched between an upper electrode and a lower electrode, an adhesion layer, and a protection film, which forms the circuit board through the steps of (1) forming the capacitor on a second substrate different from the first substrate (capacitor forming step); (2) bonding the capacitor provided on the second substrate and the first substrate together via the adhesion layer therebetween (substrate bonding step); (3) transferring the capacitor at a specified position on the first substrate by removing at least a part of the second substrate including the capacitor (capacitor transferring step); and (4) connecting the capacitor and the interconnection part disposed on the first substrate by forming through holes at specified positions of the protection film covering the capacitor and of the adhesion layer, respectively (connecting step).

In the above capacitor forming step, a releasing layer is formed on the second substrate and then the lower electrode, the dielectric layer and the upper electrode are laminated on the releasing layer to form the capacitor. In the step of transferring the capacitor, the releasing layer is removed, by which the capacitor is made so as to be transferred onto the first substrate.

Furthermore, after the lower electrode, the dielectric layer and the upper electrode are laminated on the second substrate to form the capacitor; the second substrate is removed, by which the capacitor is made so as to be transferred onto the first substrate.

In addition, after forming a releasing layer, the lower electrode, the dielectric layer and the upper electrode are laminated in this order on the second substrate to form the capacitor, the upper electrode is patterned in a specified pattern, and at least the releasing layer or the second substrate is removed, by which the capacitor is made so as to be transferred onto the first substrate.

Moreover, in the present invention, an electronic circuit board with a built-in capacitor is formed through the steps of (1) forming grooves at specified positions on a second substrate different from the first substrate (groove forming step); (2) forming a releasing layer, the capacitor and the junction metal film in this order on the second substrate including the grooves (capacitor forming step); (3) bonding the capacitor provided on the second substrate and the first substrate together via the junction metal film therebetween (substrate bonding step); (4) transferring the capacitor at a specified position on the first substrate by removing at least one of the delaminaion layer and the second substrate (capacitor transferring step); and (5) connecting the capacitor and the interconnection part disposed on the first substrate by forming through holes at specified positions of the protection film covering the capacitor (connecting step).

Furthermore, the capacitor provided on the second substrate and the first substrate are bonded together via the anisotropic conductive adhesion layer therebetween, and at least a part of the second substrate including the capacitor is removed, by which the capacitor is made so as to be transferred at a specified position on the first substrate.

Further, after the lower electrode, the dielectric layer and the upper electrode are laminated on a releasing layer formed on the second substrate to form the capacitor, the releasing layer is removed to thereby transfer the capacitor onto the first substrate.

In addition to this, after a releasing layer, the lower electrode, the dielectric layer and the upper electrode are laminated in this order on the second substrate to form the capacitor, the upper electrode is patterned in a specified pattern. Thereafter, at least the releasing layer or the second substrate is removed, by which the capacitor is made so as to be transferred onto the first substrate.

### BRIEF DESCRIPTION OF THE DRAWINGS

These and other features, objects and advantages of the present invention will become more apparent from the following description when taken in conjunction with the accompanying drawings wherein:

FIGS. 1A through 1K are sectional views showing a manufacturing process of a first embodiment of an electronic circuit board with a built-in capacitor according to the present invention;

FIGS. 2A through 2K are sectional views showing a manufacturing process of a second embodiment of an electronic circuit board with a built-in capacitor according to the present invention;

FIGS. 3A through 3H are sectional views showing a manufacturing process of a third embodiment of an electronic circuit board with a built-in capacitor according to the present invention;

FIGS. 4A through 4H are sectional views showing a manufacturing process of a fourth embodiment of an electronic circuit board with a built-in capacitor according to the present invention;

FIGS. 5A through 5G are sectional views showing a manufacturing process of a fifth embodiment of an electronic circuit board with a built-in capacitor according to the present invention;

FIGS. 6A through 6H are sectional views showing a manufacturing process of a sixth embodiment of an electronic circuit board with a built-in capacitor according to the present invention;

FIGS. 7A through 7J are sectional views showing a manufacturing process of a seventh embodiment of an electronic circuit board with a built-in capacitor according to the present invention;

FIG. 8 is a graph showing a correlation between formative temperature and lattice constant of a platinum thin film; and

FIG. 9 is a graph showing component distributions in a first electrode, a dielectric layer and second electrode of the thin-film capacitor shown in the first embodiment shown in FIG. 1K.

### DETAILED DESCRIPTION OF THE PREFERRED EMBODIMENTS

In the following, embodiments of the present invention will be explained in detail with reference to the drawings.

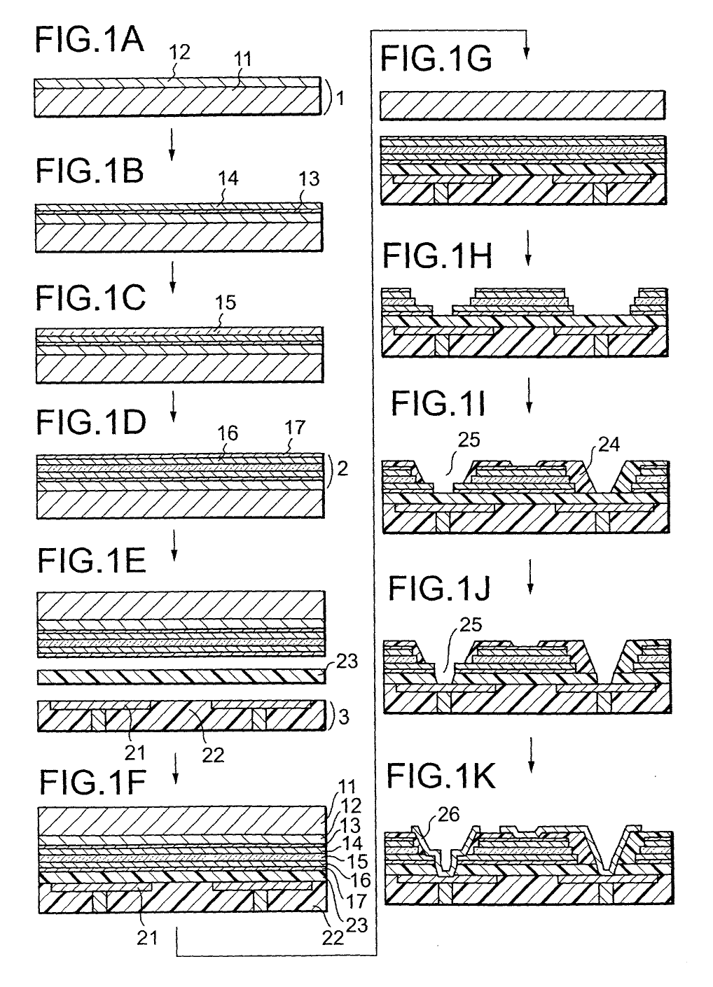

An example of a manufacturing process of an electronic circuit board with a built-in capacitor is shown in FIG. 1A through FIG. 1K as a first embodiment of the present invention.

First, a second substrate 1 is prepared as a substrate of a thin-film capacitor. In the embodiment, a silicon wafer 11 with an oxide film formed on its surface is used as the second substrate 1. A material of the second substrate 1 may be that other than the silicon wafer such as aluminum nitride or strontium titanate. However, it is necessary for the material to have a smooth surface and durability under temperatures and atmospheres in forming a thin-film capacitor having a high dielectric material.

Next, the thin-film capacitor 2 is formed on the second substrate 1. As a preprocess prior to this, a Cr thin film is formed by a well-known method, i.e. a sputtering method as a releasing layer 12 on the second substrate 1 (FIG. 1A). The releasing layer 12 is necessary in separating the second substrate 1 from the thin film capacitor 2 transformed onto a first substrate 3 in a process described later.

The releasing layer 12 can be formed with a material other than Cr thin-film as long as the material is not deteriorated, diffused, separated in forming electrode materials and the high dielectric material, and soluble in a specified etchant solution, and that the specified etchant solution causes no damage on the first substrate 3 and the like.

Also about the method of forming the releasing layer 12, a well-known method other than the sputtering such as vapor deposition or CVD (Chemical Vapor Deposition) can be employed.

In the next, a process of forming the thin film capacitor 2 on the releasing layer 12 will be explained.

A Ti thin film is first deposited as a first adhesion layer 13 to have a thickness of, for example, 2 nm with a well-known sputtering method. The Ti film is provided so as to aid a Pt thin film provided thereon as a first electrode layer 14 to adhere to other materials because the Pt thin film often used as an electrode has poor adhesion properties thereto.

Therefore, the material for the adhesion layer can be that other than Ti. However, it is necessary for the material of the adhesion layer to have good adhesion to organic materials such as polyimide and not to be dissolved by etchant solutions used when removing the releasing layer 12. About the method of Ti-thin-film deposition, a method other than sputtering such as vapor deposition or CVD can be also employed.

Following this, a Pt thin film is deposited as the first electrode layer 14 of the capacitor also by the sputtering method (FIG. 1B) to have a thickness of, for example, 100 nm.

The material of the first electrode layer 14 can be that other than Pt. However, conditions necessary for such a material are that the material takes no oxygen away from a metal oxide in contact with the first electrode layer 14, namely, it has as high free energy as possible for forming the oxide thereof, and further, that a potential barrier to electrons is high between the first electrode layer 14 and a dielectric material formed thereon, namely the work function is high. For such materials, metals of the platinum group and conductive metal oxides of the platinum group are desirable.

The deposition method of such materials can be well-known vapor deposition or CVD other than sputtering. The necessary conditions thereof are that it can form a thin film having a smooth surface and that it can desirably provide preferred orientation on the plane (111) of Pt.

As the next step, a thin film of a metal oxide having a high dielectric constant is deposited as a dielectric layer 15 of the thin film capacitor (FIG. 1C). In the embodiment, a strontium barium titanate film was deposited by the well-known sputtering method. A dielectric layer provided as an example was deposited at a deposition temperature of 450° C. to have a film thickness of 200 nm.

With respect to the material of the dielectric layer 15, any material having perovskite crystal structure with a high dielectric constant can be used other than the above strontium barium titanate. For example, strontium titanate, lead magnesium niobate, barium titanate, lead zirconium titanate, strontium bismuth tantalate, and metal oxides respectively including the above as main components are suitable.

With respect to the above described method of forming the dielectric material, any well-known methods can be employed such as CVD, MOD (Metal Organic Decomposition), and PLD (Physical Laser Deposition). However, in any method, the dielectric film requires a heat treatment at 350° C. or above for crystallization and oxygen deficiency recovery.

In the embodiment, the temperature at the deposition was set at 450° C. to carry out crystallization of strontium barium titanate. The crystallization may be carried out by another method in which an amorphous thin film is deposited with the deposition temperature set at a temperature of the order of 200° C. After this, a heat treatment is carried out with a very high temperature rising speed (Rapid Thermal Treatment abbreviated as RTA) in an oxygen containing atmosphere at 400° C. or above.

In any way, it is necessary for the metal oxide having perovskite crystal structure to be subjected to a thermal process at least at 350° C. or above.

After the deposition process of the dielectric film is completed, a Pt thin film as a second electrode layer 16 is deposited under the same condition as that for the first electrode layer 14 and further a Ti thin film as a second adhesion layer 17 is deposited under the same condition as that for the first adhesion layer 13 to complete formation of an original form of a thin film capacitor 2 (FIG. 1D).

Finally, the second substrate 1 with the thin film capacitor 2 formed thereon is heat treated in an oxygen containing atmosphere to recover oxygen deficiency in the metal oxide thin film as the dielectric layer 15 for improving capacitor characteristics. The heat treatment was carried out at for example, 500° C. for 30 minutes in a 100% oxygen atmosphere.

By passing through the above steps, the thin film capacitor 2 is formed on the second substrate 1 with a relative dielectric constant of about 500 and a static capacity of about 2 μF/cm².

As a next step, a first substrate 3 is prepared. In the embodiment, a substrate was used on which there were formed an LSI element and electrodes 21 as rearrangement interconnections. Therefore, on the surface of the first substrate 3, on which the thin film capacitor 2 provided on the second substrate 1 is to be transferred, there exist the electrodes 21 and an organic insulation film 22 made of polyimide, for example.

The organic insulation film 22 not only exists as an insulation layer of the rearrangement interconnection layer but also is necessary for shielding external a-rays and, when the first substrate 3 is joined to the second substrate 1, for reducing thermal distortion between the second substrate 1 and the LSI element.

The organic insulation film 22 made of polyimide is liable to cause thermal decomposition at 450° C. at which the strontium barium titanate thin film is formed. Therefore, in the prior art, it had to be said that it was technically impossible to form directly on the LSI element a thin film capacitor 2 with strontium barium titanate taken as a dielectric material.

Therefore, in the embodiment, a method is employed in which the second substrate 1, having the thin film capacitor 2 formed thereon, is bonded to the first substrate 3. In the method, the base (silicon wafer) 11 of the second substrate 1 is removed thereafter to thereby transfer the thin film capacitor 2 onto the first substrate 3. Thus, the above problem was avoided.

The method of transferring will be explained below.

In the embodiment, a method is employed in which the first substrate 3 and the second substrate 1 are bonded by a hot pressing method with the use of an organic adhesive made of heat-resistant resin.

First, the surface of the second substrate 1 on which the thin film capacitor 2 is formed and the surface of the first substrate 3 onto which the thin film capacitor is to be transferred are made to face each other. Between the two facing substrates, there is provided an adhesive made of heat-resistant resin, for example, an organic adhesion sheet 23 (FIG. 1E).

Next to this, with the above state being maintained, the two substrates are set in a parallel-plate type vacuum pressure bonder. The first substrate 3 and the second substrate 1 are then pressure bonded via the adhesion sheet 23 (FIG. 1F).

By the above step, the thin film capacitor 2 formed on the surface of the second substrate 1 is bonded to the first substrate 3 through the organic adhesion sheet 23. The organic adhesion sheet 23, becoming thereafter an insulation layer of the electronic circuit board, is required to have, in addition to good adhesion properties, excellent electrical characteristics (low dielectric constant, high resistivity, etc.).

In the embodiment, a parallel-plate type pressure bonder was used. However, other types, for example, an isostatic type, can be used.

After this, the silicon wafer 11 as a base of the second substrate 1 is removed. For this purpose, a method was employed in the embodiment, in which the Cr releasing layer 12, provided between the silicon wafer 11 and the thin film capacitor 2, was selectively dissolved by a well-known wet etching method so as to separate the silicon wafer 11.

For an etchant solution for the Cr releasing layer 12, a mixed water solution of hydrochloric acid and aluminum chloride was used as an example. The first substrate 3 and the second substrate 1 including the thin film capacitor 2 were dipped in the solution. Furthermore, there was applied an external mechanical force by an ultrasonic wave. This causes only the Cr releasing layer 12 to be selectively etched.

As a result, the silicon wafer 11 as the base of the second substrate 1 is separated from the thin film capacitor 2 bonded on the first substrate 1 to leave the thin film capacitor 2 on the first substrate 3. At this time, the thin film capacitor 2 is provided to have a structure in which the adhesion sheet 23, the second electrode layer 16, the dielectric layer 15, and the first electrode layer 14 are laminated in this order on the first substrate 3.

By passing through the above steps, as shown in FIG. 1G, the thin film capacitor 2, having good characteristics with perovskite crystal structure, has been transferred onto the LSI element as the first substrate 3.

Next to the above, the step of forming a pattern on the thin film capacitor 2 will be explained.

The Ti thin film as the first adhesion layer 13 is first patterned by an ordinary photolithography technique together with the Pt thin film as the first electrode layer 14. Next to this, the strontium barium titanate as the dielectric layer 15 is patterned in the same way by an ordinary photolithography technique. Further, the Pt thin film as the second electrode layer 16 is patterned also in the same way by an ordinary photolithography technique together with the Ti thin film as the second adhesion layer 17 (FIG. 1H).

In this way, formation of the basic pattern of the thin film capacitor 2 is completed. Following this, the steps are carried out for electrically connecting the thin film capacitor 2 to the LSI element and the first substrate 3 mounting the LSI element to make the thin film capacitor 2 function as a bypass capacitor.

In the steps, an organic insulation film 24 made of, for example, polyimide is first formed on the first substrate 3 including the thin film capacitor 2. Then, a through holes 25 are formed in the organic insulation film 24 by photolithography to expose a part of each of the electrode layers 14 and 16 (FIG. 1I).

Next, the through hole 25, in which the second electrode layer 16 is exposed, is extended through the adhesion sheet 23 to the electrode 21 by a method such as laser ablation to expose the electrode 21 provided on the first substrate 3 (FIG. 1J).

Thereafter, a metal thin film interconnection layer 26 is formed which is provided for two purposes, electrical connection with the thin film capacitor 2 and formation of a bump for soldering connection. An example of material for the metal thin film interconnection layer 26 is an alloy the main component of which is Ni. For depositing the interconnection layer 26, sputtering is employed, for example. For the pattern formation, an ordinary photolithography method was used. In this way, the electronic circuit board with a built-in capacitor is completed (FIG. 1K).

The electronic circuit board with a built-in capacitor, completed by passing through the above explained steps, makes the thin film capacitor, having a dielectric material of a metal oxide having perovskite crystal structure, function as a bypass capacitor. This can reduce signal error occurrence due to noises in power source when transmitting a high frequency signal.

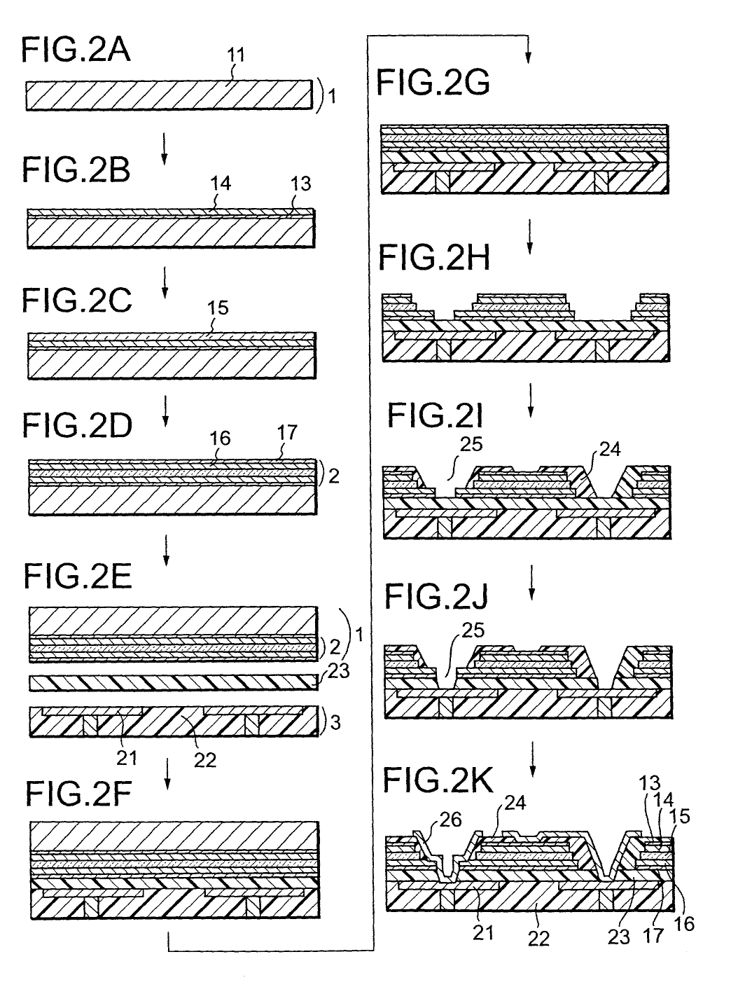

In the next, as a second embodiment, a manufacturing process of the electronic circuit board with a built-in capacitor according to the present invention will be explained by using FIG. 2A through FIG. 2K.

The difference between the first and second embodiments lies in that in the method of removing the base (silicon wafer) 11 used as the second substrate 1. In the second embodiment, the silicon wafer 11 is directly removed by a method of dissolving it. Therefore, it is not necessary to provide the Cr releasing layer 12 as shown in the first embodiment.

Thus, as the base 11 of the second substrate 1, a silicon wafer having an oxide film formed on the surface thereof was used (FIG. 2A). What is first formed on the surface of the base 11 is the Ti thin film as the first adhesion layer 13. The deposition condition is the same as that in the first embodiment.

As the next, there are followed formations of the first electrode layer 14 (FIG. 2B), the dielectric layer 15 (FIG. 2C), the second electrode layer 16, and the second adhesion layer 17 (FIG. 2D), with the same materials and the same formation conditions taken as those in the first embodiment.

Then, the step of bonding the second substrate 1 onto the first substrate 3 is carried out (FIG. 2D and FIG. 2E) with basically the same materials and formation conditions as those in the first embodiment.

Following this, the silicon wafer is directly removed which is the base 11 of the second substrate 1.

In the second embodiment, as the method of removing the silicon wafer, a well-known wet etching method was employed. A water solution of potassium hydroxide was used as the etchant solution that was kept at about 80° C. for dipping the above first substrate 3 and second substrate 1 both to have been bonded.

With this processing, the silicon wafer 11 is completely removed. At this time, a silicon dioxide film remains which was formed on the surface of the silicon wafer 11 as the second substrate 1. This, however, can be removed by dipping the first substrate 3 in a mixed water solution of fluoric acid and nitric acid.

By passing through the above steps, the thin film capacitor 2 is transferred onto the surface of the first substrate 3 (FIG. 2G).

In the embodiment, a wet etching method was employed in removing the silicon wafer 11. However, other method, for example, mechanical removing methods such as grinding or dry etching method, can be used, or some combination of them may be possible. The material used for the second substrate 1 is selected, in addition to the conditions described in the first embodiment, on condition that there is an etching method that can selectively remove the second substrate 1 and that the etching method has no adverse effect on the first substrate 3 including the thin film capacitor 2.

The steps subsequent to patterning the thin film capacitor 2 (FIG. 2H though FIG. 2K) are similar to those shown in he first embodiment (FIG. 1H through FIG. 1K). Thus, the explanations about the steps are omitted.

As explained above, an electronic circuit board with a built-in capacitor having a high quality and high reliability is completed which is provided with a built-in thin film capacitor with a dielectric layer of a metal oxide having perovskite crystal structure.

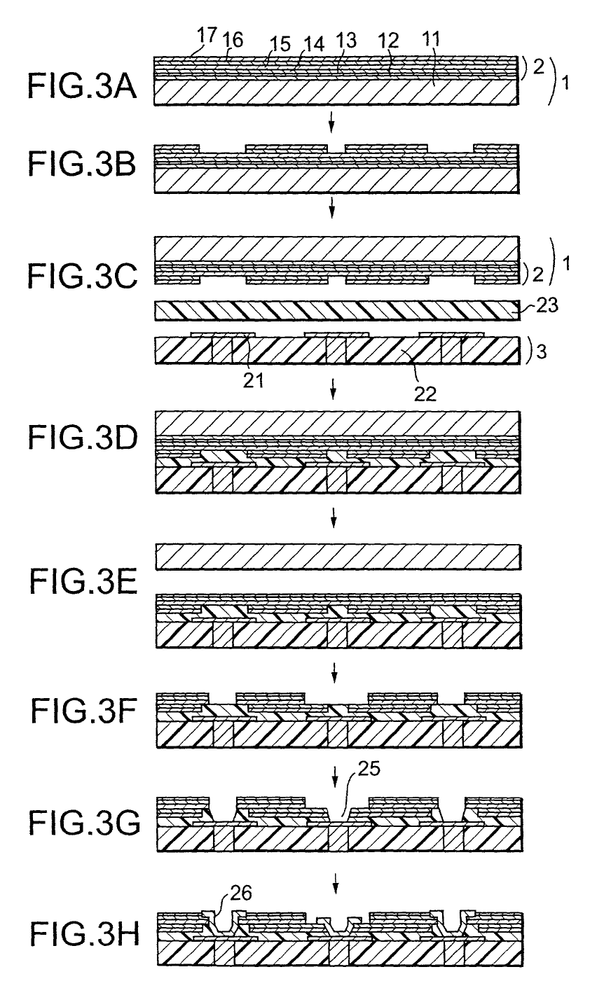

In the next, with respect to a third embodiment, a manufacturing process of the electronic circuit board with a built-in capacitor according to the present invention will be explained by using FIG. 3A through FIG. 3H.

The third embodiment is characterized in that a part of the thin film capacitor 2 is subjected to patterning prior to the step of transferring the thin film capacitor 2 onto the first substrate 3 from the second substrate 1.

First, the releasing layer 12 and the thin film capacitor 2 are formed on the silicon wafer 11 of the second substrate 1 (FIG. 3A) by the same steps as those in the first embodiment (FIG. 1A through FIG. 1D).

Next, the Ti thin film as the second adhesion layer 17 and the Pt thin film as the second electrode layer 16 of the thin film capacitor 2 formed on the second substrate 1 are patterned in bulk (FIG. 3B). Here, the patterning was carried out with an ordinary photolithography technique.

Next to this, the second substrate 1, on which the second adhesion layer 17 and the second electrode layer 16 have been patterned, and the first substrate 3 are bonded with the heat resistant organic adhesion sheet 23 put therebetween (FIG. 3C and FIG. 3D). Like in the first embodiment, for the first substrate 3 used is the LSI comprising the electrodes 21 and the organic insulation film 22. The condition of bonding at this time is the same as that described in the first embodiment.

Then, the releasing layer 12 is selectively dissolved to separate the silicon wafer 11 as the base of the second substrate 1 to transfer the thin film capacitor 2 onto the surface of the first substrate 3 (FIG. 3E). The conditions in the step are also the same as those in the first embodiment.

Following this, there is carried out patterning of the thin film capacitor 2. Both of the first adhesion layer 13 and the first electrode layer 14, which are not patterned yet, are subjected to patterning in bulk by a well-known photolithography technique. In the same way, the strontium barium titanate thin film as the dielectric layer 15 is also patterned by the photolithography technique.

Here, with this step, the patterning of the thin film capacitor 2 is completed since the second electrode layer 16 and the second adhesion layer 17 have been patterned already in the step shown in FIG. 3B (FIG. 3F).

Next, the through hole 25 is formed in the organic adhesion sheet 23 as an insulation layer by a method such as laser ablation, thereby to expose a part of the electrode 21 formed on the surface of the first substrate 3 (FIG. 3G).

Thereafter, a metal thin film interconnection layer 26 is formed which is provided for two purposes, electrical connection with the thin film capacitor 2 and formation of a bump for soldering connection. Thus, the electronic circuit board with a built-in capacitor is completed (FIG. 3H).

The electronic circuit board with a built-in capacitor, completed by passing through the above explained steps, makes the thin film capacitor, having a dielectric material of a metal oxide having perovskite crystal structure, function as a bypass capacitor. This can reduce signal error occurrence due to noises in power source that becomes a problem when transmitting a high frequency signal.

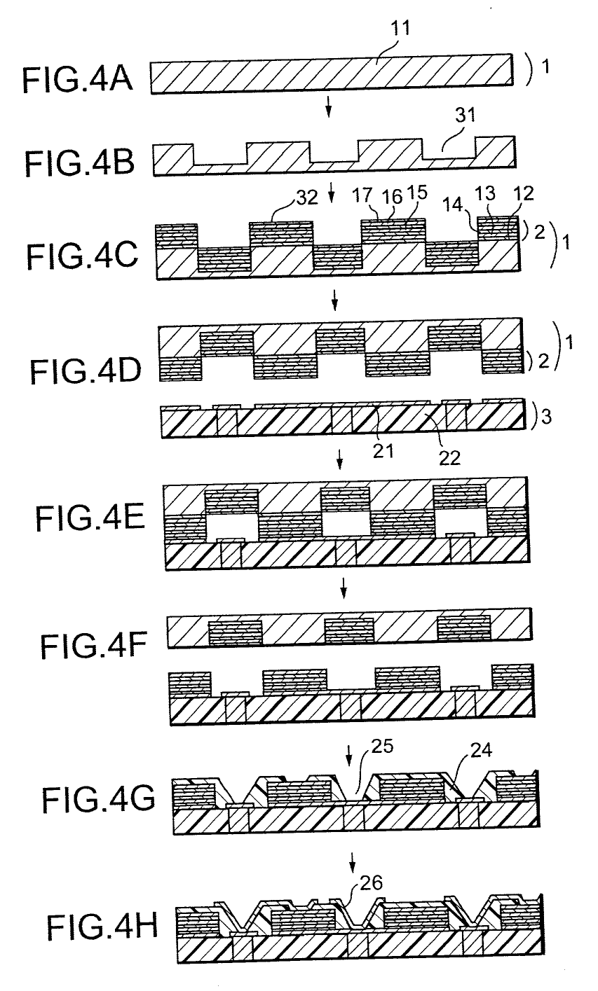

In the next, with respect to a fourth embodiment, a manufacturing process of the electronic circuit board with a built-in capacitor according to the present invention will be explained by using FIG. 4A through FIG. 4H.

The fourth embodiment is characterized in that the thin film capacitor is patterned before being transferred, and the adhesion of the thin film capacitor 2 and the first substrate 3 is realized by joining respective metal layers.

First, the silicon wafer 11 is prepared as the base of the second substrate 1 (FIG. 4A).

Next, grooves 31 are formed on the second substrate 1 with an ordinary photolithography technique so that the grooves 31 match patterns of the electrodes 21 provided on the first substrate 3 (FIG. 4B). In the fourth embodiment, with a silicon dioxide film formed on the surface of the silicon wafer 11 used as a mask, the second substrate 1 was dipped in a water solution of potassium hydroxide, by which the grooves 31 were formed.

Therefore, in addition to items described about the first embodiment, it is required for the material of the second substrate 1 that there is provided an etching method by which the second substrate 1 can be precisely patterned.

Following this, on the surface of the second substrate 1 formed with the grooves 31, the releasing layer 12 and the thin film capacitor 2 are deposited in this order. This was carried out by the same steps as those explained in the first embodiment (FIG. 1A through FIG. 1D). Continuously subsequent to the above steps of forming the thin film capacitor 2, a junction metal film 32 is formed thereon for providing electrical connection with the first substrate 3 (FIG. 4C). In the embodiment, a Pb/Sn eutectic solder was used for the junction metal film 32.

In the next, the step of transferring the thin film capacitor 2 onto the first substrate 3 will be explained.

At first, the patterns of the junction metal films 32 provided on the second substrate 1 and the patterns of the electrodes 21 provided on the first substrate 3 are positioned so that the patterns match with each other. After this, the two substrates are heated and pressed to be bonded by using a press machine (FIG. 4D and FIG. 4E). The first substrate 3 uses, like in the first embodiment, an LSI element with the electrodes 21 and the organic insulation film 22 being formed thereon.

With respect to the material of the electrodes 21, a metal film was used which contains Ni as a main component so that the electrode 21 can be sufficiently joined to the Pb/Sn eutectic solder layer of the junction metal film 32 on the upper layer of the thin film capacitor 2.

Next, by using a mixed water solution of hydrochloric acid and aluminum chloride, the releasing layer 12 formed at an interface between the second substrate 1 and the thin film capacitor 2 is selectively dissolved to separate the base 11 and the thin film capacitor 2. The step of removing the releasing layer 12 is same as that in the first embodiment. With the above steps, as shown in FIG. 4F, the thin film capacitor 2, having good characteristics with perovskite crystal structure, has been transferred onto the first substrate 3.

Subsequent to this, there are carried out the steps of electrically connecting the thin film capacitor 2 to the electrode 21 provided on the first substrate 3 including the LSI element. In the fourth embodiment, when the thin film capacitor 2 was transferred onto the first substrate 3, the second electrode layer 16, one of the electrodes of the thin film capacitor 2, has been already electrically connected to the electrode 21. Therefore, only-the step of connecting a conductor to the first electrode layer 14 becomes necessary.

In the step, an organic insulation film 24 made of, for example, polyimide is first formed on the thin film capacitor 2. Then, a through holes 25 are formed in the organic insulation film 24 by photolithography to expose a part of each of the electrode layers 14, and the electrode 21 provided on the first substrate 3 (FIG. 4G).

Finally, the metal thin film interconnection layer 26 is formed which is provided for two purposes, electrical connection with the thin film capacitor 2 and formation of a bump for soldering connection. Materials and conditions in the step are the same as those described in the first embodiment. By passing through the above steps, the electronic circuit board with a built-in capacitor is completed (FIG. 4H).

Thus provided electronic circuit board with a built-in capacitor makes the thin film capacitor, having a dielectric layer of a metal oxide having perovskite crystal structure, function as a bypass capacitor. This can reduce signal error occurrence due to noises in power source that becomes a problem when transmitting a high frequency signal.

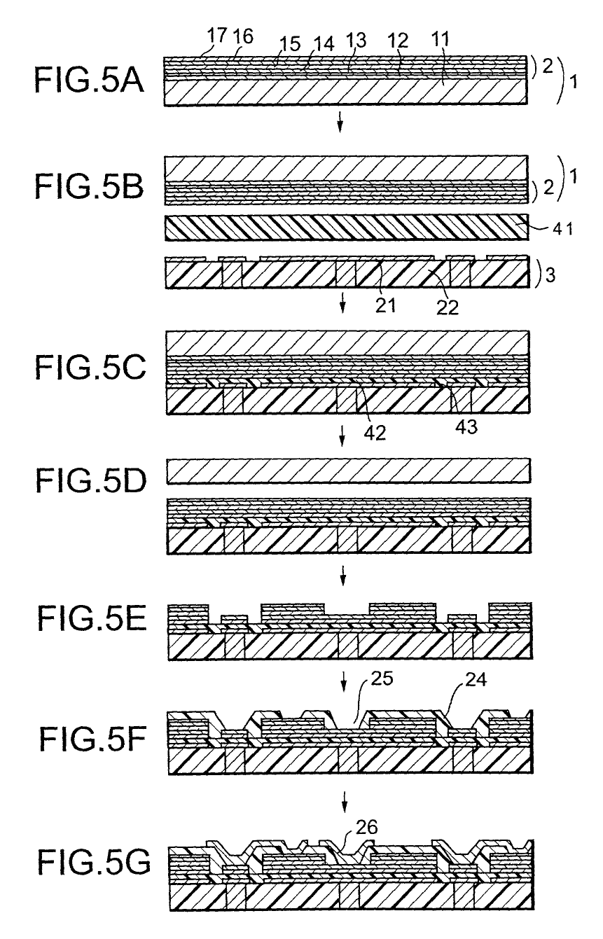

As a fifth embodiment, a manufacturing process of the electronic circuit board with a built-in capacitor according to the present invention will be explained by using FIG. 5A through FIG. 5G.

The fifth embodiment is characterized in that the electrical connection of the thin film capacitor 2 and the first substrate 3 is provided by using an aisotropic conductive adhesion film. This is a combination of the first embodiment and the fourth embodiment.

First, the releasing layer 12 and constituent materials of the thin film capacitor 2 are formed on the silicon wafer 11 of the second substrate 1. Since the steps are the same as those in the first embodiment (FIG. 1A through FIG. 1D), the explanation thereof is omitted (FIG. 5A).

Next, the first substrate 3 is prepared for transferring the thin film capacitor 2 formed on the second substrate 1 onto the first substrate 3. The first substrate 3, like that explained in the first embodiment, used an LSI element on the surface of which the electrode 21 and the organic insulation film 22 are provided.

In the fifth embodiment, however, for providing the electrical connection between the electrode 21 and the second electrode layer 16 of the thin film capacitor 2 in the step of pressure bonding as will be described later, the electrode 21 was formed so that it is protruded from the surface of the organic insulation film 22.

Next, the surface of the first substrate 3 onto which the thin film capacitor 2 is to be transferred and the surface of the second substrate 1 on which the thin film capacitor 2 is formed are made to surface each other with the anisotropic conductive adhesion film 41 sandwiched between the two facing substrates (FIG. 5B). With this state being maintained, the two substrates are set in, for example, a press machine to be heated and pressure bonded. Thus, both of the substrates are joined (FIG. 5C).

The anisotropic conductive adhesion film 41 is made of an organic insulation sheet with conductive fine particles scattered therein. By applying a pressure on the film, a portion corresponding to the protruded portion on the first substrate 3, namely the portion of the electrode 21 of the LSI element, becomes a conductive portion 42 to be electrically connected with the first electrode layer 14 of the thin film capacitor 2. A portion without the electrode 21 becomes nonconductive portion 43 to function as an organic insulation layer.

Next, by using a mixed water solution of hydrochloric acid and aluminum chloride, the releasing layer 12 formed at an interface between the silicon wafer 11 and the thin film capacitor 2 is selectively dissolved to separate the silicon wafer 11 from the thin film capacitor 2 (FIG. 5D). Since the step of removing the releasing layer 12 is the same as that in the first embodiment, the explanation thereof is omitted.

With the above steps, as shown in FIG. 5D, the thin film capacitor 2, having good characteristics with perovskite crystal structure, has been transferred onto the LSI element used as the first substrate 3.

Following this, the thin film capacitor 2 is patterned in the order of the first adhesion layer 13 and the first electrode layer 14 (bulk patterning), the dielectric layer 15, and the second electrode layer 16 and the second adhesion layer 17 (bulk patterning) (FIG. 5E). The conditions in the above steps are the same as those in the first embodiment.

Subsequent to this, there are carried out the steps of electrically connecting the thin film capacitor 2 to the LSI element and the substrate mounting the LSI element for making the thin film capacitor 2 function as a bypass capacitor. In the fifth embodiment, like in the fourth embodiment, when the thin film capacitor 2 was transferred onto the LSI element, the second electrode layer 16 has been already electrically connected to the electrode 21 through the second adhesion layer 17 and the anisotropic conductive adhesion film 41. Therefore, only the step of connecting a conductor to the first electrode layer 14 becomes necessary.

In the step, an organic insulation film 24 made of, for example, polyimide is first formed on the thin film capacitor 2. Then, through holes 25 are formed in the organic insulation film 24 by photolithography to expose a part of each of the first electrode layers 14 (substantially, the first adhesion layer 13 is exposed), and the second electrode layer 16 (FIG. 5F).

Next to this, the metal thin film interconnection layer 26 is formed which is provided for two purposes, electrical connection with the thin film capacitor 2 and formation of a bump for soldering connection. Materials and conditions in the step are the same as those in the first embodiment and explanation thereof is omitted. Thus, the electronic circuit board with a built-in capacitor is completed (FIG. 5G).

The electronic circuit board with a built-in capacitor thus completed by the above steps makes the thin film capacitor, having a dielectric layer of a metal oxide having perovskite crystal structure, function as a bypass capacitor. This can reduce signal error occurrence due for example, to noises in power source, which causes a possible problem when transmitting a high frequency signal.

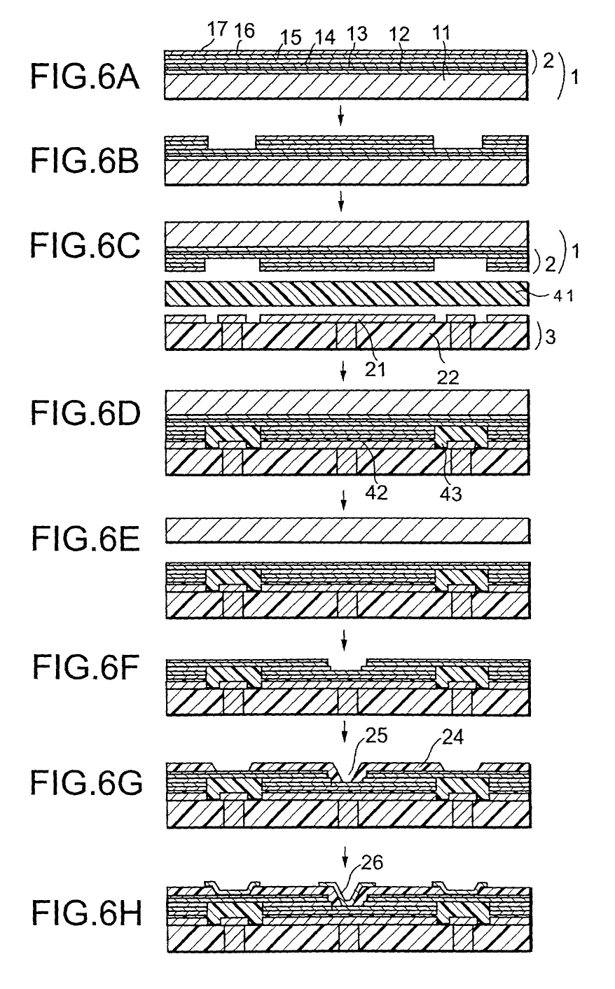

As a sixth embodiment, a manufacturing process of the electronic circuit board with a built-in capacitor according to the present invention will be explained by using FIG. 6A through FIG. 6H.

The sixth embodiment is characterized in that a part of the pattern of the thin film capacitor 2 is formed before the thin film capacitor is transferred from the second substrate 1 onto the first substrate 3, and the electrical connection between the thin film capacitor 2 and the first substrate 3 is provided by using an aisotropic conductive adhesion film 41. This is a combination of the third embodiment and the fifth embodiment.

First, the releasing layer 12 and constituent materials of the thin film capacitor 2 are formed on the silicon wafer 11 of the second substrate 1. Since the steps are the same as those in the first embodiment (FIG. 1A through FIG. 1D), the explanation thereof is omitted (FIG. 6A).

Next, the second adhesion layer 17, the second electrode layer 16 and the dielectric layer 15 of the thin film capacitor 2 formed on the second substrate 1 are patterned in order or in bulk (FIG. 6B). The patterning was carried out with an ordinary photolithography technique.

Following this, the thin film capacitor 2 formed on the second substrate 1 is transferred onto the first substrate 3 by using the anisotropic conductive adhesion film 41 (FIG. 6C through FIG. 6E). Materials and conditions of the steps are the same as those in the fifth embodiment. Thus, the explanation thereof is omitted. However, in the embodiment, since the second electrode layer 16 and the dielectric layer 15 have been patterned beforehand, registration is necessary at bonding so that the second electrode layer 16 and the dielectric layer 15 match the pattern of the electrode 21 on the first substrate 3.

Thereafter, the first adhesion layer 13, the first electrode layer 14 and the dielectric layer 15 of the thin film capacitor 2 are patterned in order or in bulk (FIG. 6F). The condition in each of the steps is the same as that in the first embodiment and the explanation thereof is omitted. In the embodiment, electric connections of the upper and lower electrodes of the thin film capacitor 2 with the electrode 21 of the LSI element are completed in the step.

Next to this, an organic insulation film 24 made of, for example, polyimide is first formed on the thin film capacitor 2. Then, through holes 25 are formed in the organic insulation film 24 by photolithography to expose a part of each of the electrode layers 14 (substantially, the first adhesion layer 13 is exposed), and the second electrode layer 16 (FIG. 6G).

Finally, a metal thin film interconnection layer 26 is formed which is provided for two purposes, electrical connection with the thin film capacitor 2 and formation of a bump for soldering connection. Thus, the electronic circuit board with a built-in capacitor is completed (FIG. 6H).

The electronic circuit board with a built-in capacitor thus completed by the above steps makes the thin film capacitor, having a dielectric layer of a metal oxide having perovskite crystal structure, function as a bypass capacitor. This can reduce signal error occurrence for example, due to noises in power source, which causes a possible problem when transmitting a high frequency signal.

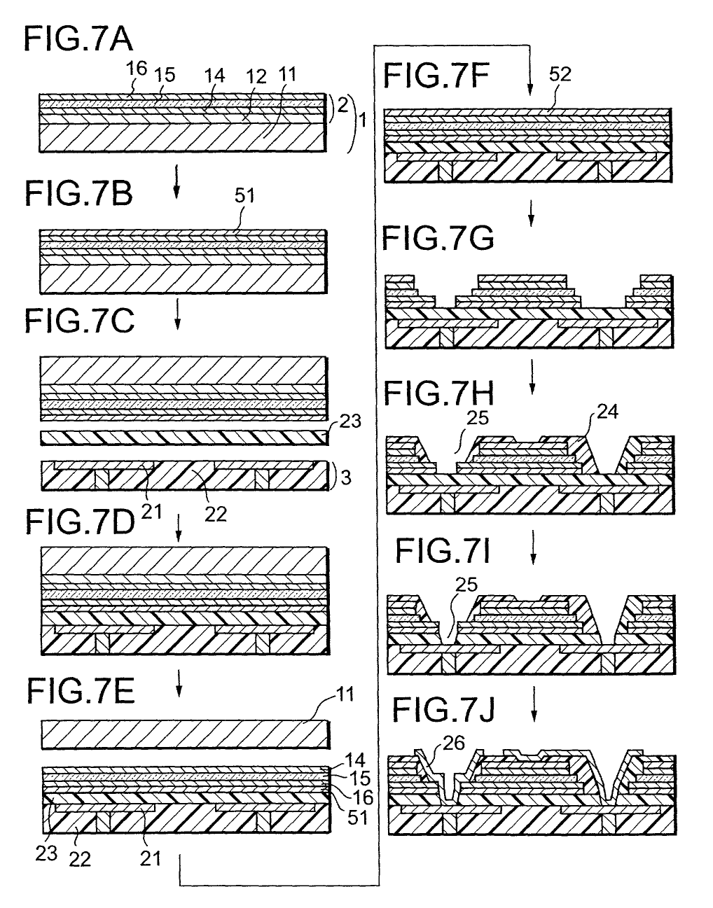

With respect to a seventh embodiment, a manufacturing process of the electronic circuit board with a built-in capacitor according to the present invention will be explained by using FIG. 7A through FIG. 7J.

The seventh embodiment is characterized in that an electrode of the thin film capacitor 2 is provided to have a structure in which an electrode as a barrier layer is laminated between a low resistance under layer electrode and the dielectric material layer. This makes it possible to avoid an adverse effect of the single under layer electrode material on film characteristic of the dielectric material layer. This is well applied to making the electrode have a low-resistance and become a thickened film for providing reduced DC resistive component and self-inductance, which are characteristics to the thin film capacitor.

The manufacturing method in the embodiment is basically in conforming to the first embodiment.

First, the silicon wafer 11 of the second substrate 1 is prepared as a substrate of the thin film capacitor 2. Conditions required for the second substrate 1 are the same as those in the description of the first embodiment.

Next, on the second substrate 1, the releasing layer 12 and the thin film capacitor 2 are formed (FIG. 7A), with the same conditions as those in the first embodiment except the first and second adhesion layers.

Then, an Al thin film is formed as a second low-resistance thin film 51 by, for example, an sputtering method to a thickness of, for example, 100 m, to constitute the second electrode layer 16 together with a Pt film formed thereunder (FIG. 7B). The deposition process of the Al film can be that other than the sputtering method such as a vapor deposition method.

The second substrate 1, having thus formed thin film capacitor 2 with the second electrode layer 16 as a lamination layer including a low-resistance thin film, is bonded with the first substrate 3 in the same way as that in the first embodiment (FIG. 7C and FIG. 7D). The first substrate 3 is also the same as that used in the first embodiment.

Thereafter, the silicon wafer 11 is removed under the same condition as that in the first embodiment (FIG. 7E). Thus, as shown in FIG. 7E, the thin film capacitor 2, having the dielectric layer 15 with perovskite crystal structure and the second electrode layer 16 as a lamination film including the low-resistance thin film, has been transferred onto the LSI element as the first substrate 3.

Following this, an Al thin film as a first low-resistance thin film 52 is deposited on the upper layer of the first substrate 3 (FIG. 7F). The film thickness was taken as, like that in the second low-resistance thin film 51, about 1 μm. This provides the first electrode layer 14 to be constituted of, like the second thin film layer 16, the lamination film of the Pt thin film and the Al thin film.

As the next step, patterning is carried out to the thin film capacitor 2 (FIG. 7G).

The first electrode layer 14 is first patterned by an ordinary photolithography technique. Subsequent to this, the strontium barium titanate layer as the dielectric layer 15 is patterned with the ordinary photolithography technique. The second electrode layer 16 is also patterned in the same way.

Thus, the basic pattern formation of the thin film capacitor is completed. After this, by passing through the same steps (FIG. 7H and FIG. 7I) as those described and shown in FIG. 1I through FIG. 1K in the first embodiment, an electronic circuit board with a built-in thin film capacitor is completed as shown in FIG. 7J.

In general, an Al material has a low melting point (about 660° C.). Therefore, when the Al material is exposed under around high temperatures necessary for forming the high dielectric material thin film, the Al material causes to form projection-like crystals called as hillocks to increase the surface roughness thereof. Thus, when a single layer of Al thin film is used as an electrode of such a thin film capacitor as is described here, the characteristics of the thin film capacitor is largely affected by such a surface profile of the Al single layer. To the worst case, the Al hillock pierces the dielectric layer thereby to cause electrical short.

In the seventh embodiment, the electrode of the thin film capacitor is provided to have a lamination structure provided with a barrier layer (here, Pt film) between the dielectric layer and the low-resistance Al electrode. This made it possible to avoid the above problem and improve performance of the capacitor. In addition, by making the thin film capacitor, having a dielectric layer of a metal oxide having perovskite crystal structure, function as a bypass capacitor, it becomes possible to reduce signal error occurrence due to noises in power source that becomes a possible problem when transmitting a high frequency signal.

In the foregoing, the electronic circuit board with a built-in thin film capacitor and its manufacturing methods were explained. Furthermore, about the performance of the thin film capacitor with a structure exemplified in FIG. 1K, crystallinity and composition of the first and second electrodes were evaluated which are typical characteristics of the electrode.

First, crystallinity of the Pt electrode formed on the uppermost layer of the second substrate 1 was evaluated by a well-known X-ray diffraction method with a resulting lattice constant of 0.3922 nm.

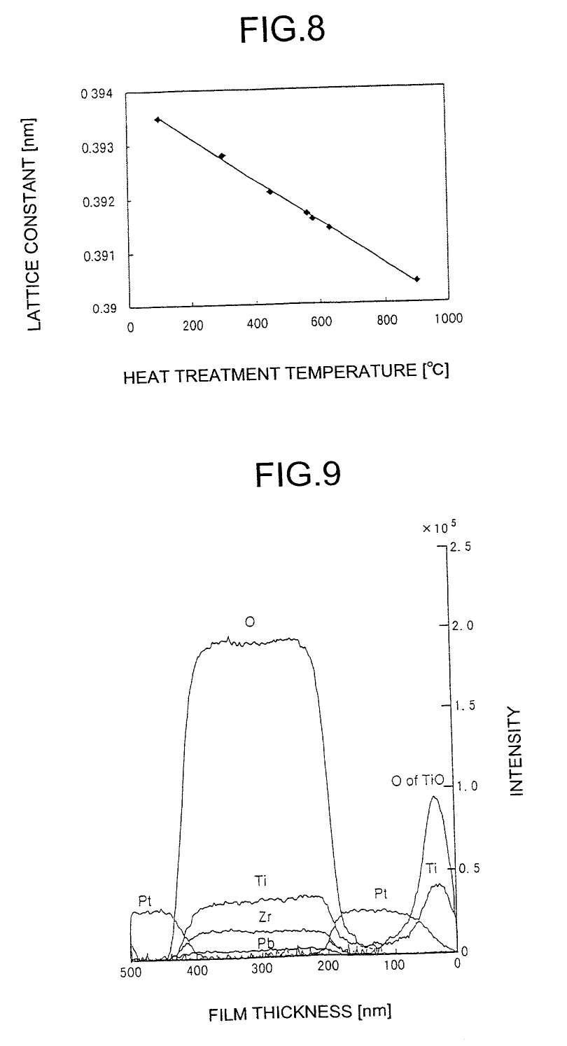

In general, the lattice constant of Pt thin film reduces by heating. Thus, the lattice constant becomes an index representing a heat history of heating or heat treatment of the substrate at deposition. FIG. 8 is a graph showing a correlation between heat treatment temperature and lattice constant of Pt, which presents that the lattice constant, is almost uniquely determined by the heat treatment temperature. From the graph, it was found that the Pt thin film used as the first electrode layer 14 according to the present invention has a heat history of being heated up to 450° C.

From the result, it can be estimated that, when a thin film capacitor with Pt electrodes is directly formed on the first substrate 3 including an LSI element, the material constituting the substrate 3 must withstand the heat treatment at 450° C.

As described above, however, the first substrate 3 includes the LSI element and is constituted with additional interconnections, electrodes, and organic films for insulation. Therefore, the first substrate 3 can not actually maintain its function when subjected to the heat history of 450° C.

While, the result of lattice constant measurement on the Pt thin film used as the second electrode layer 16 was provided as 0.3928 nm, which made it revealed from FIG. 8 that the layer 16 was subjected to heating up to about 300° C.

Next to this, the lamination film comprising the first adhesion layer 13, the first electrode layer 14, the dielectric layer 15, the second electrode layer 16 was measured about composition profiles in the direction of the depth by Auger electron spectroscopy. With respect to the measurement, the adhesion layer, both of the electrodes and the dielectric layer used Ti, Pt, and lead zirconium titanate (PZT), respectively.

The results of the measurement are shown in a graph in FIG. 9. From FIG. 9, it can be found that the Ti formed as the first adhesion layer 13 is included in the Pt layer as the first electrode layer 14. This is due to the diffusion of the Ti into the Pt layer by heat treatment, which proves that the lamination layer has a heat history of being heated up to 450° C.

From the above, it is found that the dielectric layer 15 of the thin film capacitor 2, built in the electronic circuit board shown in FIG. 1K as an example, was deposited on the top of the first electrode layer 14 and the second electrode layer 16 was deposited on the top of the dielectric layer 15, rather than being directly formed on the second substrate 3. This shows, as described above, that the separately formed thin film capacitor 2 is finally disposed on the second substrate 3.

The characteristics of thus manufactured thin film capacitor 2 were exhibited with a relative dielectric constant of about 500 and static capacity of about 2 μtF/cm².

Therefore, by using the electronic circuit board with thus formed built-in thin film capacitor 2, a high-speed signal transmission is brought into realization. In the transmission, it is possible to reduce signal error occurrence due to noises in power source that becomes a possible problem when transmitting a high frequency signal As described above, according to the present invention, an electronic circuit board with a built-in thin film capacitor having a high quality and high reliability can be formed which has such a high quality and high reliability as to cause no signal error due to noises in power source generated when transmitting a high frequency signal.

While we have shown and described several embodiments in accordance with our invention, it should be understood that disclosed embodiments are susceptible of changes and modifications without departing from the scope of the invention. Therefore, we do not intend to be bound by the details shown and described herein but intend to cover all such changes and modifications as fall within the ambit of the appended claims.

What is claimed is:

1. An electronic circuit board with a built-in capacitor comprising:
a first substrate having an interconnection part;
a capacitor having a dielectric layer sandwiched between an upper electrode and a lower electrode;
an adhesion layer; and
a protection film,
the upper electrode of the capacitor being disposed so as to be in contact with the adhesion layer for being connected to the first substrate, and
the upper electrode and the lower electrode being connected to the interconnection part of the first substrate through holes provided through the adhesion layer and the protection film, respectively.

2. An electronic circuit board with a built-in capacitor comprising:
a first substrate having an interconnection part;
a capacitor having a dielectric layer sandwiched between an upper electrode and a lower electrode; and
a protection film,
the upper electrode of the capacitor being provided with a junction metal layer thereon,
the junction metal layer being connected to the interconnection part disposed on the first substrate, and
the lower electrode being connected to the other interconnection in the interconnection part on the first substrate through a through hole provided in the protection film.

3. An electronic circuit board with a built-in capacitor comprising:
a first substrate having an interconnection part;
a capacitor having a dielectric layer sandwiched between an upper electrode and a lower electrode;
an anisotropic conductive adhesion layer; and
a protection film,
the upper electrode of the capacitor being disposed so as to be connected to the interconnection part on the first substrate via the anisotropic conductive adhesion layer, and
the lower electrode being connected to the other interconnection part of the first substrate through a through hole provided in the protection film and via the anisotropic conductive adhesion layer.

4. The electronic circuit board according to claim 1, wherein the dielectric material layer comprises a metal oxide having perovskite crystal structure.

5. The electronic circuit board according to claim 2, wherein the dielectric material layer comprises a metal oxide having perovskite crystal structure.

6. The electronic circuit board according to claim 3, wherein the dielectric material layer comprises a metal oxide having perovskite crystal structure.

7. The electronic circuit board according to claim 4, wherein said metal oxide comprises at least one selected from a group consisting of strontium titanate, strontium barium titanate, lead magnesium niobate, barium titanate, lead zirconium titanate and strontium bismuth tantalate.

8. The electronic circuit board according to claim 5, wherein said metal oxide comprises at least one selected from a group consisting of strontium titanate, strontium barium titanate, lead magnesium niobate, barium titanate, lead zirconium titanate and strontium bismuth tantalate.

9. The electronic circuit board according to claim 6, wherein said metal oxide comprises at least one selected from a group consisting of strontium titanate, strontium barium titanate, lead magnesium niobate, barium titanate, lead zirconium titanate and strontium bismuth tantalate.

10. The electronic circuit board according to claim 1, wherein each of the upper electrode and the lower electrode comprises at least two metal layers in which, compared with a resistance of one metal layer disposed to be in contact with the dielectric layer, the other metal layer has a smaller resistance.

11. The electronic circuit board according to claim 2, wherein each of the upper electrode and the lower electrode comprises at least two metal layers in which, compared with a resistance of one metal layer disposed to be in contact with the dielectric layer, the other metal layer has a smaller resistance.

12. The electronic circuit board according to claim 3, wherein each of the upper electrode and the lower electrode comprises at least two metal layers in which, compared with a resistance of one metal layer disposed to be in contact with the dielectric layer, the other metal layer has a smaller resistance.

13. The electronic circuit board according to claim 1, wherein the first substrate is a semiconductor device comprising the interconnection part and a transistor part.

14. The electronic circuit board according to claim 2, wherein the first substrate is a semiconductor device comprising the interconnection part and a transistor part.

15. The electronic circuit board according to claim 3, wherein the first substrate is a semiconductor device comprising the interconnection part and a transistor part.

16. A method of manufacturing an electronic circuit board with a built-in capacitor wherein,
said electronic circuit board comprises a first substrate with an interconnection part, a capacitor having a dielectric layer sandwiched between an upper electrode and a lower electrode, an adhesion layer, and a protection film, and
said method comprising:
a capacitor forming step for forming the capacitor on a second substrate different from the first substrate;
a substrate bonding step for bonding the capacitor provided on the second substrate and the first substrate together via the adhesion layer therebetween;
a capacitor transferring step for transferring the capacitor at a specified position on the first substrate by removing at least a part of the second substrate including the capacitor; and
a connecting step for connecting the capacitor and the interconnection part disposed on the first substrate by forming through holes at specified positions of the protection film covering the capacitor and of the adhesion layer, respectively.

17. The method according to claim 16 wherein,
said capacitor forming step comprises a step of forming a releasing layer on said second substrate and laminating on said releasing layer said capacitor comprising the lower electrode, the dielectric layer and the upper electrode, and
said capacitor transferring step comprises a step of transferring said capacitor onto the first substrate by removing said releasing layer.

18. The method according to claim 16 wherein,
said capacitor forming comprises a step of laminating said lower electrode, said dielectric layer and said upper electrode on the second substrate to form the capacitor, and
said capacitor transferring step comprises a step of removing the second substrate to transfer the capacitor onto the first substrate.

19. The method according to claim 16 wherein,
said capacitor forming step comprises a step of laminating a releasing layer and said capacitor comprising the lower electrode, the dielectric layer and the upper electrode on the second substrate, and patterning the upper electrode, and
said capacitor transferring step comprises a step of removing at least one of said releasing layer and said second substrate to transfer the capacitor onto the first substrate.

20. A method of manufacturing an electronic circuit board with a built-in capacitor wherein,
said electronic circuit board comprises a first substrate with an interconnection part, a capacitor having a dielectric layer sandwiched between an upper electrode and a lower electrode, a junction metal film, and a protection film, and
said method comprises:
a groove forming step for forming a groove at a predetermined position on a second substrate;
a capacitor forming step for forming a releasing layer, the capacitor and the junction metal film on a surface of said second substrate including the base surface of said groove;
a substrate bonding step for bonding the capacitor provided on the second substrate and the first substrate via the junction metal film therebetween;
a capacitor transferring step for transferring the capacitor at a specified position on the first substrate by removing at least one of the delaminaion layer and the second substrate; and
a connecting step for connecting the capacitor to the interconnection part disposed on the first substrate by forming a through hole at a predetermined position of the protection film covering the capacitor.

21. A method of manufacturing an electronic circuit board with a built-in capacitor wherein,
said electronic circuit board comprises a first substrate with an interconnection part, a capacitor having a dielectric layer sandwiched between an upper electrode and a lower electrode, an anisotropic conductive adhesion layer, and a protection film, and
said method comprises:
a capacitor forming step for forming the capacitor on a second substrate;
a substrate bonding step for bonding the capacitor provided on the second substrate and the first substrate via the anisotropic conductive adhesion layer therebetween;
a capacitor transferring step for transferring the capacitor at a predetermined position on the first substrate by removing at least a part of the second substrate including the capacitor; and
a connecting step for forming a through hole at a predetermined position of the protection film covering the capacitor and connecting the capacitor to the interconnection part disposed on the first substrate through the through hole and via the anisotropic conductive adhesion layer.

22. The method according to claim 21 wherein,
said capacitor forming step comprises a step of forming a releasing layer on the second substrate and laminating the lower electrode, the dielectric layer and the upper electrode on the releasing layer to form the capacitor, and
said capacitor transferring step comprises a step of removing said releasing layer to transfer the capacitor onto the first substrate.

23. The method according to claim 21 wherein,
said capacitor forming step comprised a step of laminating a releasing layer and a capacitor comprising the lower electrode, the dielectric layer and the upper electrode, and patterning the upper, and
said capacitor transferring step comprises a step of removing at least one of the releasing layer and the second substrate to transfer the capacitor onto the first substrate.
